(19) United States
(12) Patent Application Publication
(10) Pub. No.: US 2018/0376537 A1
(43) Pub. Date: Dec. 27, 2018

(54) Multiple Heaters in a MEMS Device for Drift-Free HREM with High Temperature Changes

(71) Applicant: Technische Universiteit Delft, Delft (NL)

(72) Inventor: Hendrik Willem Zandbergen, Delft (NL)

(21) Appl. No.: 15/741,450

(22) PCT Filed: Jun. 30, 2016
(86) PCT No.: PCT/NL2016/050462

§ 371 Date: Jan. 2, 2018

(30) Foreign Application Priority Data
Jun. 30, 2015 (NL) 2015055

(51) Int. Cl. H05B 3/26; B01L 3/00; H01J 37/20; H01J 37/26

(52) U.S. Cl. CPC H05B 3/26; H01J 37/26; H01J 37/20; B01L 3/502707

(57) ABSTRACT

The use of MEMS-based micro heaters for heating experiments in electron microscopy is known. Heating of a sample typically relates to a temperature increase or decrease of at least 50 K, and often at least 200 K. The present invention provides an improved heating system for use in an observation tool requiring low drift of <0.2 nm/sec, such as an electron microscope, comprising two cooperating and integrated MEMS-based micro heaters (21,22) spaced apart at a mutual distance of less than 10 mm. A first heater is a master heater (21) and capable of receiving a first amount of power, a second heater is a slave heater (22) and capable of receiving a second amount of power, wherein the first and second amounts of power are in a range from 0 mW to the total amount of power. A thermometer is measuring the temperature of the master heater in use with an accuracy of better than ±10 mK, and a power controller prevents variation in the total amount of power received by keeping the total amount of power constant with an accuracy of better than ±5 pW and divides the total amount of power over the at least two heaters.

### FIELD OF THE INVENTION

The present invention is in the field of a heater in a MEMS device for use in an observation tool requiring low drift, such as an electron microscopy.

### BACKGROUND OF THE INVENTION

The present invention is in the field of a heater in a MEMS device e.g. for use in electron microscopy.

MEMS-based micro heaters in electron microscopes are typically located on a MEMS holder or sample holder, which latter can be considered as a MEMS based device. The use of these heaters for heating experiments in electron microscopy is known. With the prior art holders one can obtain a high mechanical stability (low vibrations and a low specimen drift) which is typically good enough to make sub 0.1 nm resolution images. With this low drift that can be realized with these MEMS based devices under a stable temperature the drift of the sample is far better than that with, what may be considered, a conventional heating holder; i.e. conventional heating holders are considered not suited for such heating experiments. With a MEMS based device one can, in case of an electron microscope (e.g. High Resolution Electron Microscope (HREM)), obtain high quality high resolution imaging. However, when there is a sub-stantial temperature increase (like 40 K or more), typically an equilibration time is needed for the MEMS/MEMS based device and the goniometer of the HREM, to obtain the required low drift to record HREM images. During this thermal equilibration time and in particular in the first period of time it is impossible to obtain high resolution images and thus after an increase in temperature waiting times of a few minutes are needed and thus the immediate changes in a sample under observation cannot be recorded. For prior art MEMS heaters only a small temperature rise of a few degrees can be done without introducing a drift that prevents taking high resolution images. To mimic technological heat treatments a temperature increase or decrease of at least 50 K, and often at least 200 K is needed. An increase or decrease of at least 500 K is also envisaged. Such larger temperature changes lead to specimen drifts that prevent high resolution imaging during the temperature change and at least a few minutes thereafter.

In an alternative approach, in the case of drift one could reduce the electron beam exposure time. If the same noise level for an image is required the electron beam intensity has to be increased with the same ratio as the reduction of the exposure time. For instance instead of an exposure time of 1 sec, one can take 0.1 sec with a 10 times higher intensity. The higher dose could be unattainable per se, but if attainable it can result in electron beam induced damage to a sample under inspection. Thus a shorter exposure time in combination with a higher beam intensity is often not possible. In fact it is often preferred to have an as low as possible electron beam intensity.

Some prior art documents may be mentioned for further understanding background art.

US 2005/142036 A1 recites a micro-fluidic heating system, which comprises a micro-fluidic control element for providing a chamber, a flow path and a valve, and a main body for heating the inside of the chamber in contact with the micro-fluidic control element, wherein the micro-fluidic control element consists of an upper substrate for providing the chamber, the flow path and the valve, and a lower substrate as a thin film bonded to the upper substrate, and the main body consists of a membrane in which heating means and suction holes are formed, and support member for supporting the membrane, and the heating means is partially in contact with the lower substrate of the chamber to heat the inside of the chamber, so that thermal transfer efficiency becomes maximized and temperature of each chamber may be independently controlled in the case of configuration having chambers arranged in array. The document apparently recites two heaters, but nothing with respect to a relation between these two heaters.

WO 2015/084169 A1, also of the TU Delft, recites a low specimen drift holder and cooler for use in microscopy, and a microscope comprising said holder. The present invention is in the field of microscopy, specifically in the field of electron and focused ion beam microscopy (EM and FIB). However it application is extendable in principle to any field of microscopy, especially wherein a specimen is cooled or needs cooling.

Creemer et al. (amongst others one of the present inventors) in “A MEMS reactor for Atomic-scale Microscopy of Nanomaterial Under Industrially Relevant Conditions”, J. Microelectromechanical Systems, IEEE, Vol. 19, nr. 2, April 2010, p. 254-264, recites a microelectromechanical systems (MEMS) nanoreactor that enable high resolution transmission electron microscopy (HRTEM) of nanostructured materials with atomic scale resolution during exposure to reactive gases at 1 atm of pressure.

The present invention therefore relates to an improved heater, which solves one or more of the above problems and drawbacks of the prior art, providing reliable results, without jeopardizing functionality and advantages.

### SUMMARY OF THE INVENTION

The present invention relates to a heating system according to claim 1 for use in an observation tool requiring low drift, such as an electron microscopy, an experimental set-up according to claim 9, and a method according to claim 10.

With respect to the used terminology the following terms are detailed.

A MEMS heater relates to a resistance based heater, mostly embedded in a thin non-conductive membrane, like SiN.

A MEMS heating chip relates to a chip that contains a MEMS heater.

A MEMS heating chip holder (or chip holder) relates to a holder that supports the MEMS heating chip and is placed in the goniometer of the observation tool.

A MEMS heating effected system relates to a system that is effected or can be effected by a temperature change of the MEMS heater leading to local thermal expansions or contractions and which comprises at least the MEMS heating chip and the MEMS heating chip holder, and possibly also parts of the goniometer.

A MEMS heating system relates to a total of the MEMS heating chip, the MEMS heating chip holder with its electrical connections to the MEMS heating chip, a heater control box and the software to steer that control box.

A sample relates to a sample that is placed on the MEMS heater.

A sample device relates to a device for receiving a sample, such that experiments can be performed on the sample and observation of the results of such experiments is possible, such as in an electron microscope.

With the present MEMS heating system it is now possible to keep the power supply to a MEMS heater chip constant. This is achieved by providing at least two heaters integrated in the MEMS heater chip, at least one being a so-called main or master heater and one being a slave heater, preferably having similar characteristics. Throughout the description a reference to a master (or slave) heater may also relate to a number of master (or slave) heaters, the number e.g. being from 2-100. Inventors are using two heaters (or more) in which one is a slave heater which allows the operator to keep the power put into the whole MEMS heater chip constant while (quickly) changing the power (and thus the temperature) of the master heater. When performing an experiment, one may start the experiment with only power provided to the slave heater, e.g. 15 mW, i.e. only the slave heater is receiving power. The slave heater may for instance have an increased temperature of 1000 K. Thereafter the MEMS heating effected system, i.e. including the chip, the holder, the goniometer, and at least to some extent the microscope, is thermally stabilized for a period of time, typically from a few minutes to an hour, depending on the height of the increased temperature, and depending on heat characteristics of the various components of the MEMS heating chip holder and the rest of the MEMS heating effected system, such as parts of the goniometer, such as heat conductance and heat capacity. The master heater, still being at a temperature of the total system, e.g. slightly above room temperature, can be set at the required temperature by providing power, e.g. from 0 to 5 mW, with a simultaneous decrease in power to the slave heater, in the example from 15 mW to 10 mW. With the invention one can start immediately (within a second) with e.g. a HREM recording, e.g. at 650 K. In a further stage the amount of power to the slave heater may be reduced, e.g. to 5 mW, and at the same time the power to the master heater may be increased, in the example to 10 mW, giving rise a temperature increase of the main hater, such as to 1000 K. Again, measuring and/or HREM recording can start immediately. Such is not possible with the prior art set-ups.

In order to control the temperature precisely a thermometer is provided for measuring the temperature of the master heater accurately, i.e. more precise than ±50 mK, typically more precise than ±10 mK, such as more precise than ±5 mK; values of ±1 mK-±2 mK have been established by the present inventors. For temperature control a feedback is given by the temperature controller, e.g. to the power controller, in order to adjust the amount of power received, if required, and to adjust as required, and all the time keeping the total power to the heaters the same.

For dividing a total power over the heaters and especially for control of the amount of power received by the heaters a power controller is provided. Within the present system total power control is with an accuracy of better than ±1 μW, typically better than ±0.1 μW, preferably better than ±0.05 μW, and more preferably better than ±0.02 μW, such as better than ±0.01 μW (10 nW). Power control to the individual heaters is comparable, but is found to be somewhat less critical.

The power controller is typically located elsewhere, such as outside the electron microscope, in the tip, in the electron microscope or in a controller thereof, or is located in the MEMS heating chip holder, or in the MEMS heating chip. As located elsewhere the electrical contacts provide power control and power input. A similar consideration may be the case for the temperature controller, which may be combined or integrated in the power controller; however thermometers are typically provided in the heaters themselves, in particular in the master heater.

The present heating device is especially suited for in-situ experiments in electron microscopy, specifically high resolution microscopy. It provides a simple and effective construction of an experimental set-up, comprising a tip 91 (or holder), a cup for receiving the MEMS heater chip, and on the MEMS heater chip (100) the present MEMS heaters. Further fast and controlled temperature changes are possible. Contrary to prior art device the use in high resolution electron microscopy now effectively provides the high resolution, due to e.g. a low drift: the drift is so small after e.g. a (local) temperature change of 200° C. that immediately one can do HREM imaging with a resolution of 1 Å; under such conditions prior art device have a drift of at least a factor (2-10) higher.

In order to control drift even further various thermal insulators in between the above elements may be incorporated; however, the present heating device by itself already provides the envisaged characteristics. It is noted that if only thermal insulators would be provided, that provision of, and likewise variation in provision of, power to the tip of the experimental set-up has a very noticeable effect in terms of drift; drift is still not controlled adequately.

The present heating system typically comprises software for controlling the heating system. It may further comprise calibration data and further software to make use of this calibration data e.g. during experiments.

Typical dimensions of the present MEMS heater chip are a length of 5-50 mm, a width of 2-10 mm, and a thickness that may vary functionally, e.g. at a MEMS heater being very thin, as detailed below, and at a supporting part being 0.2-1 mm.

Thereby the present invention provides a solution to one or more of the above mentioned problems and drawbacks.

Advantages of the present description are detailed throughout the description.

### DETAILED DESCRIPTION OF THE INVENTION

The present invention relates in a first aspect to a heating system according to claim 1, which is for use in a sample device in an (HR)electron microscope, as indicated above. The heating device therein comprises at least two cooperating MEMS-based heaters for receiving a total amount of heat, one referred to as master heater and the other as slave heater. In a similar approach more MEMS based heaters may be present, such as a total of 2-100. In view of complexity, and especially electrical contacting, it is preferred to use 2-4 heaters. For many situations 2-3 heaters are sufficient. Some thereof will function as master heater, and others as slave heater. Power is controlled and divided over the respective slave and master heaters, as indicated above. The first heater or master heater receives a first amount of heat, and the second heater or slave heater receives a second amount of heat. Further a temperature controller is provided, the temperature controller comprising a thermometer, the thermometer measuring the temperature of the master heater. The thermometer typically uses a variation in electrical resistance to determine the temperature; it may therefore us electrical contacts for communication with the outside world. It is therefore preferred to calibrate the thermometer (e.g. T[K] versus R[Ω]) before use, such as batch-wise. In this latter respect it is noted that variation from batch to batch may occur, such as in thickness of a metal (Pt) layer; intra batch variation is typically negligible for the present thermometer. The controller is for measuring a temperature of the master heater and maintaining or increasing or decreasing the temperature as required. It has been found important for experiments to measure the temperature locally very precisely, in order to e.g. have a good correlation with ex-situ experiments. Also a power controller is provided, wherein the power controller limits variation in the total amount of power very accurately and divides the total amount of power over the at least two heaters precisely. A first amount and second amount of power provided to (and received by) (at least one) master heater and (at least one) slave heater, respectively, may vary from 0 to the total amount.

Temperature and electric resistance are typically measured using a so-called 4-points set-up.

The present device comprises a supporting structure for supporting the micro heaters. The supporting structure may be fixed to a holder, such as by screws. The supporting structure typically comprises at least one electrical contacts or connectors, e.g. for heating the micro heaters. The supporting structure further comprises “windows” for performing TEM or HREM experiments, the windows being very thin. Likewise at least one cut-out may be provided.

In an example the more than one (two or more) master heater may provide a temperature gradient over the sample device; therewith sub-parts of the sample are kept at a first temperature and other sub-parts are kept at a second temperature. Sub parts in between will have intermediate temperatures. As such simple or complex temperature gradients within the sample can be provided in a controlled manner. Likewise also temperature increases and decreases can be provided in sub-parts of the sample.

The sample may be fixed to the heating device, in particular to the master heater(s) thereof.

In an example of the present heating device the master heater and slave heater have at least one characteristics that varies less than 10% relative between master heater and slave heater, selected from a maximum power, power consumption control, a size, a material of which the heater is constructed, a supporting structure for the heater, a 2- or 3-dimensional layout of the heater, and an Ohmic resistance. In other words, especially concerning functional aspects, the (at least one) master heater and (at least one) slave heater can be substantially the same or may be different in certain aspects and then be controlled substantially the same. As such an excellent imaging is achieved.

In an example of the present heating device the master and slave heater are both embedded, such as in a thin membrane of e.g. silicon nitride. Typically the membranes have the same or very similar dimensions. Such has the advantage that the behaviour in terms of heat dissipation to the rest of the chip is very much the same.

In an example of the present heating device at least one MEMS based heaters 21,22 comprises a membrane 21a,22a, the membrane having a thickness of 100 nm-2 μm, preferably 200 nm-1 μm, such as 300 nm-800 nm, a length of 10-2000 μm, preferably 200 nm-1 μm such as 400-800 μm, and a width of 10-2000 μm, preferably 100 nm-1000 μm, such as 200-850 μm. The membrane can be manufactured with e.g. semiconductor process techniques. It is large enough to perform experiments under an electron microscope. The membrane is relatively thin.

In an example of the present heating system the power control of a total power is better than ±10 nW, e.g. when about 10 mW of power is received, hence better than about 1 PPM. Such results in a temperature control of better than 10 mK. In addition a maximum power provision of the (at least one) master and (the at least one) slave heater is from 0.1-100 mW, typically from 0.5-50 mW, such as 1-20 mW, e.g. 10 mW. It is noted that such a power is very low and clearly a required control thereof is preferably much better than ±1% relative thereof, e.g. better than 0.1%.

In an example of the present heating device the MEMS based heaters are selected from a one or two dimensional structure, such as a spiral, an ellipsoid, a grid, a branched structure, and a circle. Also combinations thereof, such as multiple (2 or more) spirals, may be present. Microelectromechanical systems (MEMS) relate to a technology of very small devices, such as membranes, free standing structures, oscillators, transducers, ultrasonic devices, etc. Any structure that can be produced in a (semi-conductor) process is considered suitable; boundary conditions relate further to a size of the membrane. Typically dimensions of an area of the MEMS heater are 10-1000 μm by 10-1000 μm, preferably 20-500 μm by 20-500 μm, more preferably 50-400 μm by 50-400 μm, such as 100-300 μm by 100-300 μm. The area of the MEMS heater, and likewise any other area, may be rectangular, square, hexagonal, or the like. The dimensions of the present heater line itself are typically a thickness of 0.1-5 μm, such as 50-200 nm, a width of 1-50 μm, preferably 2-20 μm, such as 5-15 μm, and a length of 10-10000 μm, preferably 50-7500 μm, more preferably 100-5000 μm, even more preferably 200-4000 μm, such as 500-3000 μm. A preferred example is a double spiral, having 2-5 double spirals, and a length of 600-4200 μm. Also stacked heaters could be used, such as a SiN membrane, a first Pt heater, a SiN membrane, a second Pt heater, and a third SiN membrane. So very small heating devices can be used, or a multitude thereof, giving the present advantages, having a relatively low power, allowing a good control, etc.

In an example of the present heating device the MEMS based heaters are one of free-standing, or partially or fully supported by a membrane. Preferably all MEMS-based heaters in one heating device have a same geometry, e.g. all being embedded in a membrane. It is preferred to use a supporting membrane, the membrane supporting 90-100% of the present MEMS heater. In terms of surface area, the surface area of the membrane is in an example 1.5-100 times that of the heater itself (e.g. a spiral on a membrane), such as 2-10 times as large. It has been found that with such MEMS heaters the best image resolution having the lowest drift can be obtained. Also a large degree of design freedom is obtained thereby.

There are several design issues for a single heater that may be taken into account: in order reduce heat dissipation of the heater to the chip the membrane is a lot wider that the heater. If the distance of the heater to the Si of the chip is small the heater is in part on the Si, the heat dissipation will be large. In such a case a change in the temperature of the heater will result in a change in the temperature of the Si of the chip, which will result in drift due to thermal expansion of the holder. In case of the main and slave heater the requirement of a small heat dissipation is found far less stringent because the power and thus the heat dissipation is kept constant.

In an example of the present heating device the at least two heaters are made of a similar material, preferably a same material, selected from Si, SIC, Pt, W and Mo. Especially Pt and Mo are found to be particularly suited. With these materials good control is obtained and good manufacturability.

It is noted that the master heater and slave heater have a behaviour (response) upon increasing and decreasing power provision. In an example of the present heating device this varies <1% (δW/δsec) between the master heater and slave heater. In other words the behaviour of the present (at least one) master heater and (at least one) slave heater are in terms of power consumption and heat generation, under the same boundary conditions, practically the same. If more than one master and slave heater are present in this respect at least one master heater is matched with at least one slave heater, respectively, and so on. Each master heater has a matched slave heater in the example.

The above secures that a change in temperature of the master heater does not result in a change of temperature of the chip c.q. sample device and thus no drift is observed. It is preferred to have the at least two heaters being located at a mutual very small distance, preferably as close as possible, typically less than 5 mm, more typically less than 1 mm, such as of less than 0.5 mm. The MEMS heaters may be located on one membrane or the like. In between MEMS heaters, e.g. a slave heater and a main heater, some material may be present, such as Si.

Also in terms of geometrical characteristics the master and slave heater can be matched.

For instance, the master heater and slave heater having a width, and a length, that are matched. For instance, the width of the master heater is 0.9-1.1 times the width of the slave heater, and/or the length of the master heater is 0.9-1.1 times the length of the slave heater. With respect to the length and width, the width of the master heater is from 0.5-3 mm, the length of the master heater is from 0.3-3 mm.

In a second aspect the present invention relates to an experimental set-up according to claim 9. The set-up comprises a tip, which tip may be a standard electron microscope tip, or a more advance tip. It further comprises a so-called cup connected to the tip. The cup may be considered a half open space for easy entry and removal of a sample device. It further may comprise a sample device in the cup, and the present heating device.

In a third aspect the present invention relates to a method of operating the present experimental set-up in an in-situ electron microscope experiment according to claim 10. Therein e.g. drift is reduced by providing power only to the slave heater, then thermally stabilizing the experimental setup, and further reducing power provision to the slave heater with a first amount, and at the same time increasing power to the master heater with the first amount. A total power is preferably maintained constant, and the total power is distributed over the master heater and slave heater in an example.

In an example of the present method power reception and power division over the heaters is controlled within 200 nW, typically within 100 nW, and values within 10-50 nW have been established, i.e. extremely accurate. For sake of comparison typical prior art devices may control power provision relatively accurate, e.g. within 100-250 nW, but power consumption or reception typically upon temperature change (i.e. increase or decrease) less accurate than 1 mW, and typically >5 mW. In comparison to the prior art especially control of a total power consumption is much better.

The main heater may be controlled better than ±5 mK, and power reception thereof better than ±50-100 nW, whereas requirements for the total power may be somewhat more relaxed, e.g. ±100 mK and power provision of ±1-2 μW. In a further optimized system the power reception and control of the main heater may be a factor 5 smaller (better), e.g. ±1 mK, ±10-20 nW.

In an example of the present method drift is controlled within 0.2 nm/sec, and typically within 0.05 nm/sec.

In an example of the present method temperature control is within 10 mK, preferably within 5 mK, such as within 2 mK, i.e. extremely accurate. For sake of comparison some prior art devices control temperature less accurate than 0.1 K, typically even worse; however temperature control during increase and decrease of temperature was hardly possible. In an example of the present method the power of the slave heater is increased to a predetermined value resulting in a temperature from 283-1800 K, i.e. a small increase to somewhat above room temperature to a large increase. After this increase the power input is kept constant precisely. After the total system has reached a thermal equilibrium such that the drift is very small the master heater can be used for heating e.g. a sample and performing temperature experiments (keeping the total power unchanged).

In an example of the present method when the power of the master heater is increased to a predetermined value resulting in a temperature from 283-1800 K, e.g. a temperature of interest in terms of experimental conditions, simultaneously the power to the slave heater is decreased, e.g. to an initial value of the master heater. Such is found to result in optimal results in terms of drift and resolution, taking into account experimental boundary conditions.

In an example of the present method a sample in the sample device is studied at the predetermined temperature. In a further example a sample in the sample device is studied during the increase of temperature. The latter can simply not be achieved with prior art systems.

In an example of the present method the MEMS heater chip is calibrated, and wherein calibration results are used for fine tuning power provision and division. In order to be able to compensate for variation of heat radiation and dissipation to e.g. the holder the present MEMS heater chip is calibrated. Such compensation reduces drift. The calibration is aimed at determining an amount of power dissipation and radiation under various temperature conditions: the slave heater may be at a temperature of 273-1800 K and the master heater being at a temperature slightly above room temperature, the master heater may be at a temperature of 273-1800 K and the slave heater being at a temperature slightly above room temperature, or both heaters may be at a temperature of 273-1800 K. The results thereof for a specific MEMS heater chip, or a production series thereof, can be stored; as such the stored data can be considered a further example of the present heating system. The results can subsequently be used in experiments to correct for these dissipation and radiation variations, such as by (embedded) software. The correction typically relates to providing (slightly) more or less power, either total power, power to at least one of the master heater and slave heater, or all of the aforementioned.

The one or more of the above examples and embodiments may be combined, falling within the scope of the invention.

### EXAMPLES

The invention is further detailed by the accompanying figures, which are exemplary and explanatory of nature and are not limiting the scope of the invention. To the person skilled in the art it may be clear that many variants, being obvious or not, may be conceivable falling within the scope of protection, defined by the present claims.

### FIGURES

The invention although described in detailed explanatory context may be best understood in conjunction with the accompanying figures.

FIG. 1 shows a top view of the present device.

FIG. 2 shows a side view of the present device.

FIG. 3 shows a side view of a prior art device.

FIG. 4a-d show HREM images.

FIG. 5 shows an illustration of drift behaviour when changing the temperature.

### DETAILED DESCRIPTION OF THE FIGURES

In the figures:
100 MEMS heater chip
21 master heater
21a membrane
22 slave heater
22a membrane
25 prior art MEMS heater
31 electrical contacts
33 prior art electrical contacts
51 fixation means
52 fixing block
53 prior art fixing block
56 clamp plate
56a screw
57 prior art clamp
71 window
75 cut-out section
81 support
91 tip

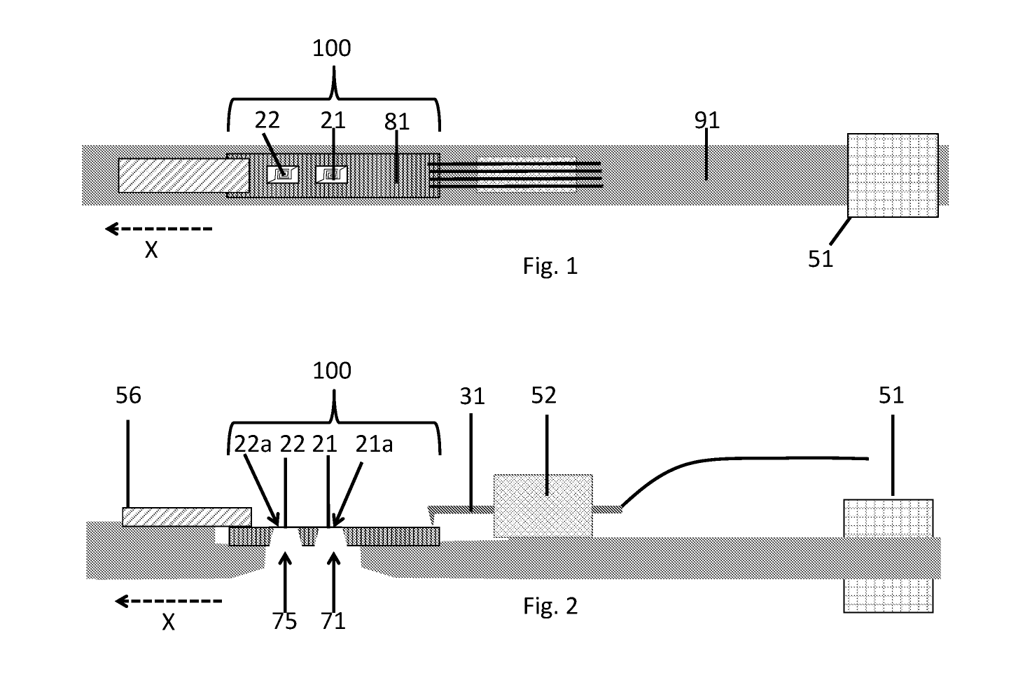

FIG. 1 shows a top view of the present device. The MEMS heater chip 100 is typically used in combination with a tip 91. At a right hand side the tip is attached and fixed to a microscope using fixation means 51 typically for fixing in an x-direction. The x-direction is indicated with an arrow in the figure. The present device comprises a master heater 21 and a slave heater 22, being at a mutual distance of 0.2 mm. The heating device is fixed to the tip. For fixing the device to the tip, e.g. a clamp plate 56 is used including a screw 56a. The clamp plate may be a separate entity, may be part of the tip, or may be part of the present heating device.

FIG. 2 shows a side view of the present device. In addition to the elements identified in FIG. 1 also the following details are indicated. The master heater is located “above” a window 71, allowing inspection of a sample with an electron microscope. A sample (not shown) is typically placed above the window as well. The slave heater is typically placed on a membrane with a cut-out section 75 in the device; the cut out section 75 and the window 71 have similar dimensions. The cut-out section and window may partially or fully overlap, or may be separate. Typically the master heater is placed on a membrane 21a, and the slave heater is also placed on a membrane 22a. Present in the tip is a block 52 for fixing one or more electrical contacts 31. The block and contacts can in principle also be present in the present heating device.

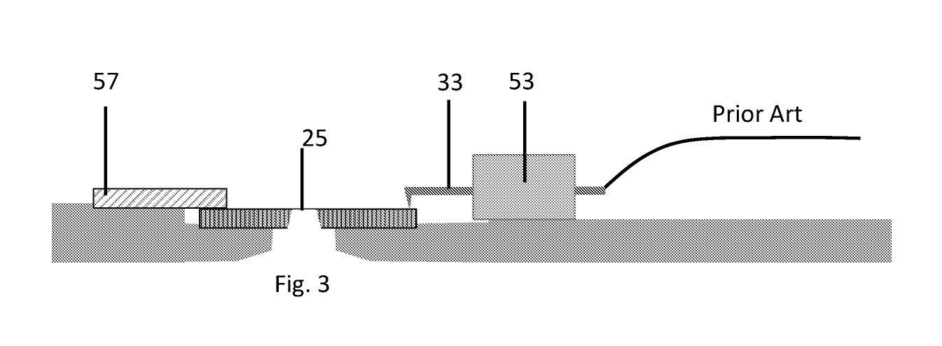

FIG. 3 shows a side view of a prior art device. Therein a MEMS heater 25 is provided. Further electrical contacts 33, a block 53 for fixing electrical contacts, and a clamp 57 are provided.

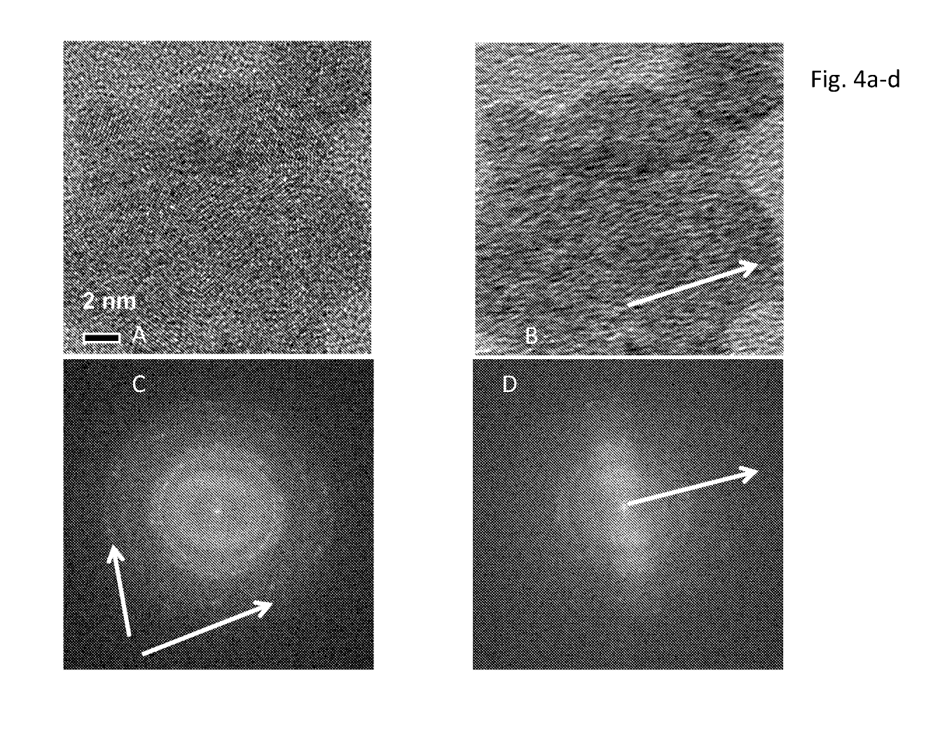

FIG. 4a shows a HREM (TEM) (300 keV) image of typical test sample comprising small and crystalline Au particles deposited on an amorphous SiN substrate with an exposure time of 0.5 sec and a drift of approximately 0.5 A/sec; such a drift is typically acceptable as the resolution is not hampered by specimen drift. In case of drift lattice planes (planes of Au atoms) being more or less perpendicular to the drift direction will be blurred or even absent on the image. In FIG. 4a the drift is so low that the image is almost clear and lattice planes (as present in the specimen) can be observed in all directions.

FIG. 4b shows a HREM image of the same area As in FIG. 4a with an exposure time of 0.5 sec and a drift of approximately 5 A/sec; such a drift is typically not acceptable as the resolution is severely hampered by specimen drift. As a result of drift the image is almost not clear and details of the image of the individual particles are lost. The arrow indicates the drift direction.

FIG. 4c shows a Fourier Transform substantially of the image of FIG. 4a. A Fourier Transform may be used to determine the loss of resolution. The image shows a largely regular pattern, reflecting the underlying regular pattern of the image. As some domains can be observed in the image of FIG. 4a, also domains in this decomposed image reflected as a series of points, are visible. The arrows indicate so-called 1.1 A fringes, indicative for the regular pattern in at least two substantially perpendicular directions.

Likewise FIG. 4d shows a Fourier Transform substantially of the image of FIG. 4b; especially in the drift direction no clear points are observed any more, hence no crystal-lographic information in that direction is apparently present in the image of FIG. 4b. Perpendicular to the drift direction the resolution of FIG. 4b is comparable to that of FIG. 4a as can be observed.

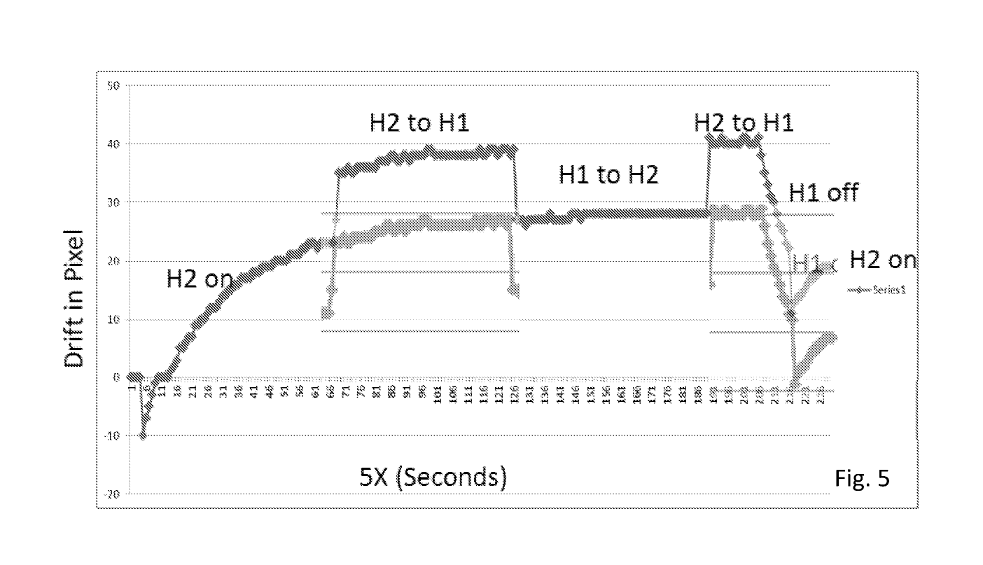

FIG. 5 shows an illustration of drift behaviour when changing the temperature. On the y-axis the drift in terms of pixels is given. The size of a pixel is about 1 nm. On the horizontal axis time is given, wherein each point represents 5 seconds.

The figure represents experiments with two heaters on one chip, one indicated with H2, for TEM imaging, and one, indicated with H1, for keeping a total power into the sample device (or chip) the same. In a first stage the heater for imaging is powered. The result thereof is a drift. Over time the drift levels out. At a certain point in time all power is transferred to the other heater (H1). As a result a sudden jump in position of the sample can be observed in the figure. However, the drift itself, so not taking into account the jump, continues along a same line (similar slope and levelling out). Such is indicated in the figure by a second line, wherein the jump is subtracted from the drift observed.

The figure shows that by first heating the slave heater until the drift is low enough (substantially horizontal in the figure) it is now possible to start providing power (heating) of the heater that is intended to actually heat the sample, without having a drift. Heating can be done at any speed (temperature increase), as long as the total amount of power as received is kept constant, as is the case with the present device.

Possibly a slight drift may remain, at an order of magnitude smaller than without the present device. The remaining drift can be compensated for, e.g. by control, by calibrating, or a combination thereof.

A further advantage with the present device is that a larger heat flux towards the sample is now possible with a further advantage that smaller membranes can be used and less bulging occurs.

The figures have been detailed throughout the description.

1-15. (canceled)

16. Heating system for use in an observation tool requiring low drift of <0.2 nm/sec, comprising
(1) a MEMS heater chip (100), the MEMS heater chip comprising
(1a) at least two cooperating and integrated MEMS-based micro heaters (21,22) for receiving a total amount of power, the MEMS heaters spaced apart at a mutual distance of less than 10 mm,
(1b) a supporting structure (81) for supporting the micro heaters, the supporting structure having at least one window (71),
(2) a temperature controller, the temperature controller comprising a thermometer, characterized in that
a first heater is a master heater (21) and capable of receiving a first amount of power,
a second heater is a slave heater (22) and capable of receiving a second amount of power,
wherein the first and second amounts of power are in a range from 0 mW to the total amount of power,
wherein the thermometer measuring the temperature of the master heater in use with an accuracy of better than ±10 mK, and
(3) a power controller, wherein the power controller prevents variation in the total amount of power received by keeping the total amount of power constant with an accuracy of better than ±5 μW and divides the total amount of power over the at least two heaters.

17. Heating system according to claim 16, wherein the master heater and slave heater have at least one characteristics that varies less than 10% relative between first heater and second heater, selected from a maximum power, power control, a size, a material of which the heater is constructed, a supporting structure for the heater, a 2- or 3-dimensional layout of the heater, and an Ohmic resistance.

18. Heating system according to claim 16, wherein the master and slave heater are both embedded in silicon nitride.

19. Heating system according to claim 16, wherein at least one MEMS based heater comprise a membrane (21a,22a), the membrane having a thickness of 100 nm-2 μm, a length of 10-2000 μm, and a width of 10-2000 μm.

20. Heating system according to claim 16, wherein a maximum power provision of each of the master and slave heater is from 1-100 mW.

21. Heating system according to claim 16, wherein the MEMS based heaters are selected from a one or two-dimensional structure, a spiral, an ellipsoid, a grid, a branched structure, and a circle.

22. Heating system according to claim 16, wherein the MEMS based heaters are one of free-standing, or partially or fully supported by a membrane.

23. Heating system according to claim 16, wherein the at least two heaters are made of a similar material, selected from Si, SiC, Pt, W and Mo.

24. Experimental set-up for use in an electron microscope comprising a tip (91), a cup in the tip, a sample device in the cup, and the heating system (100) of claim 16.

25. Method of operating an experimental set-up according to claim 24 in an in-situ electron microscope experiment, comprising the steps of
providing power only to the slave heater,
thermally stabilizing the experimental set-up, and
reducing power provision to the slave heater with a first amount, and at the same time increasing power to the master heater with the first amount, and
keeping a total power constant.

26. Method according to claim 25, wherein power provision and power division are controlled within 1000 nW, drift is controlled within 0.2 nm/sec, and wherein temperature is controlled within 10 mK.

27. Method according to claim 25, wherein the power of the slave heater is increased to a predetermined value resulting in a temperature from 283-1800 K, and wherein thereafter the power of the master heater is increased to a predetermined value resulting in a temperature from 283-1800 K, and simultaneously the power to the slave heater is decreased.

28. Method according to claim 25, wherein a sample in the sample device is studied at the predetermined temperature.

29. Method according to claim 25, wherein a sample in the sample device is studied during the increase of temperature.

30. Method according to claim 25, wherein the MEMS heater chip is calibrated, and wherein calibration results are used for fine tuning power provision and power division, in view of heat radiation.
